(19) United States
(12) Patent Application Publication
(10) Pub. No.: US 2009/0184431 A1
(43) Pub. Date: Jul. 23, 2009

(54) Liquid epoxy resin composition and flip chip semiconductor device

(75) Inventors: Kazuaki Sumita, Gunma-ken (JP); Toshio Shiobara, Gunma-ken (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd.

(21) Appl. No.: 12/289,268

(22) Filed: Oct. 23, 2008

Related U.S. Application Data
(63) Continuation of application No. 10/842,492, filed on May 11, 2004.

(30) Foreign Application Priority Data
May 12, 2003 (JP) 2003-132956

(51) Int. Cl. H01L 23/48; C07F 7/08; C08L 63/00; C08K 3/36

(52) U.S. Cl. 257/778; 524/869; 523/428; 524/847; 257/E23.169

(57) ABSTRACT

A liquid epoxy resin composition comprising (A) a liquid epoxy resin, (B) an aromatic amine curing agent comprising at least 5% by weight of a specific aromatic amine compound, and (C) an inorganic filler has a low viscosity for ease of working, cures into a cured product which has improved adhesion to the surface of silicon chips, and offers an encapsulated semiconductor device that does not suffer a failure even at a reflow temperature of 260-270° C., does not deteriorate under hot humid conditions, and does not peel or crack on thermal cycling.

This application is a Continuation Application of co-pending application Ser. No. 10/842,492 filed on May 11, 2004, for which priority is claimed under 35 U.S.C. § 120, and which claims priority under 35 U.S.C. §119 of Application No. 2003-132956 filed in Japan on May 12, 2003, the entire contents of which are hereby incorporated by reference.

### FIELD OF THE INVENTION

This invention relates to a liquid epoxy resin composition for the encapsulation of semiconductors, especially flip chip type semiconductor devices, and more particularly, to a liquid epoxy resin composition which has a low viscosity and working efficiency and cures into a product having improved adhesion to the surface of silicon chips and especially photosensitive polyimide resins, nitride films and oxide films, improved resistance to humidity and to thermal shocks at high temperatures above the reflow temperature of 260° C., and is thus suitable as encapsulation material. It also relates to a flip chip type semiconductor device which is encapsulated with the liquid epoxy resin composition in the cured state.

### BACKGROUND OF THE INVENTION

The trend toward smaller sizes, lighter weights and increased capabilities in electrical equipment has brought a shift in the dominant semiconductor mounting process from pin insertion to surface mounting. Progress of semiconductor devices toward a higher degree of integration entails the enlargement of dies to a size as large as 10 mm or more per side. For semiconductor devices using such large size dies, greater stresses are applied to the die and the encapsulant during solder reflow. Such stresses are problematic because separation occurs at the interface between the encapsulant and the die or substrate, and the package cracks upon substrate mounting.

From the expectation that the use of leaded solders will be banned in the near future, a number of lead-substitute solders have been developed. Since most substitute solders have a higher melting temperature than the leaded solders, it has been considered to carry out reflow at temperatures of 260 to 270° C. At higher reflow temperatures, more failures are expected with encapsulants of prior art liquid epoxy resin compositions. Even with flip chip type packages which have raised no substantial problems in the prior art, the reflow at such high temperatures brings about serious problems that cracks can occur during the reflow and the encapsulant can peel at interfaces with chips or substrates. Also undesirably, cracks can occur in the resin, substrate, chip and bumps after several hundreds of thermal cycles.

Also the progress toward higher integration raises a problem of hindered infiltration. In flip-chip semiconductor devices, the infiltration ability is worsened as the pitch between bumps becomes narrower.

The patent publications pertinent to the present invention include

JP-A 10-158366,

JP-A 10-231351,

JP-A 2000-327884,

JP-A 2001-055486,

JP-A 2001-055487, and

JP-A 2001-055488.

### SUMMARY OF THE INVENTION

An object of the invention is to provide a liquid epoxy resin composition for semiconductor device encapsulation which cures into a cured product that has improved adhesion to the surface of silicon chips and especially photosensitive polyimide resins and nitride films and improved toughness, does not suffer a failure even when the temperature of reflow elevates from the conventional temperature of nearly 240° C. to 260-270° C., does not deteriorate under hot humid conditions as encountered in PCT (120° C./2.1 atm), and does not peel or crack over several hundred cycles of thermal cycling between −65° C. and 150° C. Another object of the invention is to provide a flip chip type semiconductor device which is encapsulated with a cured product of the liquid epoxy resin composition.

The invention pertains to a liquid epoxy resin composition comprising (A) a liquid epoxy resin, (B) an aromatic amine curing agent, and (C) an inorganic filler. It has been found that better results are obtained when the aromatic amine curing agent (B) contains at least 5% by weight of an aromatic amine compound having the following general formula (1):

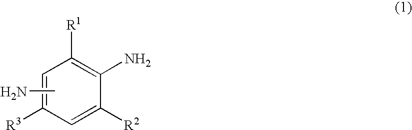

wherein each of R¹ to R³ is independently a monovalent hydrocarbon group having 1 to 6 carbon atoms, CH₃S— or C₂H₅S—. The resulting liquid epoxy resin composition is low viscous and easy to work, effectively adherent to the surface of silicon chips and inter alia, photosensitive polyimide resins and nitride films, especially nitride films, does not deteriorate under hot humid conditions as encountered in PCT (120° C./2.1 atm), and is fully resistant to thermal shocks. The composition is thus suited as an encapsulant for large die size semiconductor devices.

In a liquid epoxy resin composition, the aromatic amine compound of formula (1), by virtue of unique substituent groups included therein, invites relatively fast heat cure, but ensures a long pot-life and imparts improved mechanical, electrical, heat resistant and chemical resistant properties to cured products, as compared with conventional aromatic amine curing agents. The liquid epoxy resin composition comprising the aromatic amine compound of formula (1) becomes effectively adherent to the surface of silicon chips and inter alia, photosensitive polyimide resins and nitride films, is drastically improved in thermal shock resistance, and maintain satisfactory properties even under hot humid conditions.

As compared with conventional aromatic amine curing agents, the aromatic amine curing agent used in the invention has a low viscosity so that the resulting composition can be reduced in viscosity. This is advantageous especially in the case of narrow gap flip chip type semiconductor devices because working efficiency is improved and the generation of voids during casting and curing steps is avoided. The composition is also suited as an encapsulant for large die size semiconductor devices.

Accordingly, the present invention provides a liquid epoxy resin composition comprising

(A) a liquid epoxy resin,

(B) an aromatic amine curing agent comprising at least 5% by weight of an aromatic amine compound having the formula (1), and

(C) an inorganic filler.

Also contemplated herein is a flip chip type semiconductor device which is encapsulated with the liquid epoxy resin composition in the cured state as an underfill.

### BRIEF DESCRIPTION OF THE DRAWING

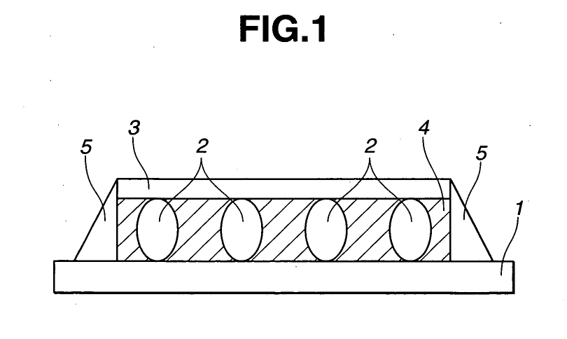

The only FIGURE, FIG. 1 is a schematic view of a flip chip type semiconductor device according to one embodiment of the invention.

### DETAILED DESCRIPTION OF THE INVENTION

In the liquid epoxy resin composition of the invention serving, any epoxy resin may be used as the liquid epoxy resin (A) as long as it contains three or less epoxy functional groups in a molecule and is liquid at normal temperature. Preferably the liquid epoxy resin has a viscosity at 25° C. of up to 2,000 poises, especially up to 500 poises. Useful liquid epoxy resins include bisphenol type epoxy resins such as bisphenol A epoxy resins and bisphenol F epoxy resins, naphthalene type epoxy resins and phenyl glycidyl ethers. Of these, epoxy resins which are liquid at room temperature are desirable.

The epoxy resin may comprise an epoxy resin of the structural formula (4) or (5) shown below insofar as infiltration ability is not compromised.

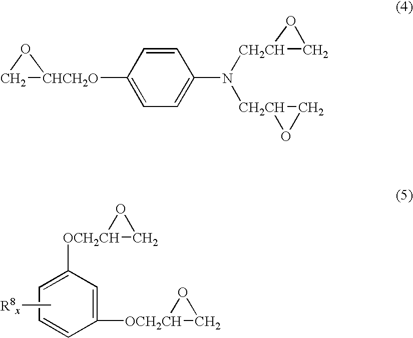

Herein, R⁸ is hydrogen or a monovalent hydrocarbon group having 1 to 20 carbon atoms, preferably 1 to 10 carbon atoms, more preferably 1 to 3 carbon atoms. Exemplary of the monovalent hydrocarbon group are alkyl groups such as methyl, ethyl and propyl, and alkenyl groups such as vinyl and allyl. The subscript x is an integer of 1 to 4, especially 1 or 2.

It is recommended that the epoxy resin of formula (5), if compounded, be used in an amount of at least 25% by weight, preferably at least 50% by weight, more preferably at least 75% by weight based on the entire epoxy resins. If the content of the epoxy resin of formula (5) is less than 25 wt %, the composition may have an increased viscosity or the heat resistance of cured products may lower. The upper limit may be even 100% by weight.

The epoxy resin of formula (5) is commercially available, for example, under the trade name of RE600NM from Nippon Kayaku Co., Ltd.

The liquid epoxy resin preferably has a total chlorine content of not more than 1,500 ppm, and especially not more than 1,000 ppm. When chlorine is extracted from the epoxy resin with water at an epoxy resin concentration of 50% and a temperature of 100° C. over a period of 20 hours, the water-extracted chlorine content is preferably not more than 10 ppm. A total chlorine content of more than 1,500 ppm or a water-extracted chlorine level of more than 10 ppm may exacerbate the reliability of the encapsulated semiconductor device, particularly in the presence of moisture.

The aromatic amine curing agent (B) used herein contains at least 5% by weight, based on the entire curing agent, of an aromatic amine compound having the general formula (1).

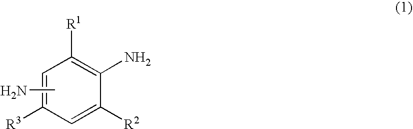

Herein R¹ to R³ are independently selected from among a monovalent hydrocarbon group having 1 to 6 carbon atoms, CH₃S— and C₂H₅S—.

The monovalent hydrocarbon groups represented by R¹ to R³ are preferably those having 1 to 6 carbon atoms, more preferably 1 to 3 carbon atoms, for example, alkyl groups such as methyl, ethyl, propyl, isopropyl, butyl, isobutyl, tert-butyl and hexyl, alkenyl groups such as vinyl, allyl, propenyl, butenyl and hexenyl, phenyl groups, and halo-substituted monovalent hydrocarbon groups in which some or all of the hydrogen atoms are substituted with halogen atoms (e.g., chlorine, fluorine and bromine), such as fluoromethyl, bromoethyl and trifluoropropyl.

Specific, non-limiting examples of the aromatic amine compound having formula (1) include diethyltoluenediamine, dimethylthiotoluenediamine, and dimethyltoluenediamine.

The aromatic amine curing agent (B) contains at least 5% by weight, preferably 10 to 100% by weight, more preferably 20 to 100% by weight, based on the entire curing agent, of the aromatic amine compound having formula (1). If the aromatic amine compound having formula (1) is less than 5% by weight of the entire curing agent, there arise problems like an increased viscosity, a reduced bond strength and cracks.

The curing agents other than the aromatic amine compound having formula (1) are preferably aromatic diaminodiphenylmethanes such as 3,3′-diethyl-4,4′-diaminophenylmethane, 3,3′,5,5′-tetramethyl-4,4′-diaminophenylmethane, and 3,3′,5,5′-tetraethyl-4,4′-diaminophenylmethane, and aromatic amines such as 2,4-diaminotoluene, 1,4-diaminobenzene and 1,3-diaminobenzene.

Among the aromatic amine curing agents, a curing agent which is liquid at normal temperature may be compounded directly. If an aromatic amine curing agent is solid at normal temperature, direct compounding of that aromatic amine curing agent with the epoxy resin results in a resin compound which has an increased viscosity and is awkward to work. It is then preferred to previously melt and mix the normally solid aromatic amine curing agent with the epoxy resin, more preferably in a predetermined proportion at a temperature in the range of 70 to 150° C. for 1 to 2 hours. At a mixing temperature below 70° C., the aromatic amine curing agent may be less miscible with the epoxy resin. A temperature above 150° C. can cause the aromatic amine curing agent to react with the epoxy resin to increase its viscosity. A mixing time of less than 1 hour is insufficient to achieve intimate mixing of the aromatic amine curing agent with the resin, inviting a viscosity increase. A time of more than 2 hours may allow the aromatic amine curing agent to react with the epoxy resin to increase its viscosity.

The total amount of the aromatic amine curing agent used herein should preferably be such that the molar ratio of the liquid epoxy resin to the aromatic amine curing agent, (A)/(B), is in the range from 0.7/1 to 1.2/1, more preferably from 0.7/1 to 1.1/1, even more preferably from 0.85/1 to 1.05/1. If the compounding molar ratio is less than 0.7, unreacted amino groups are left, probably resulting in a lower glass transition temperature and poor adhesion. With a molar ratio in excess of 1.2, there is a possibility that the cured product becomes hard and brittle enough for cracks to form during the reflow operation or thermal cycling.

As the inorganic filler (C) in the inventive composition, any inorganic filler known to be useful for lowering the expansion coefficient may be added. Specific examples include fused silica, crystalline silica, aluminum, alumina, aluminum nitride, boron nitride, silicon nitride, magnesia and magnesium silicate. Of these, spherical fused silica is desirable for achieving low viscosity. The inorganic filler may have been surface treated with a silane coupling agent or the like although the inorganic filler can be used without surface treatment.

The preferred semiconductor device to be encapsulated with the epoxy resin composition of the invention is a flip chip type semiconductor device having a gap size in the range of about 10 μm to about 200 μm. When the liquid epoxy resin composition is used as an underfill which should exhibit both improved penetration and a lower linear expansion, it is advantageous to include an inorganic filler having an average particle size at most about one-tenth as large and a maximum particle size at most one-half as large as the size of the flip chip gap (between the substrate and semiconductor chip in a flip chip semiconductor device). In a more preferred embodiment, the inorganic filler has an average particle size of 0.1 to 5 μm and contains not more than 0.1% by weight (based on the entire inorganic filler) of a fraction having a particle size of at least one-half of the gap size in a flip chip type semiconductor device. A filler with an average particle size of less than 0.1 μm may cause a viscosity buildup. In excess of 5 μm, such coarse particles will clog gaps, leaving them unfilled.

The method of measuring a particle size of at least one-half of the gap size is, for example, a sieve analysis method involving mixing the inorganic filler with deionized water in a weight ratio of 1:9, subjecting the mixture to ultrasonic treatment for fully disintegrating agglomerates, sieving through a screen having an opening equal to one-half of the gap size, and weighing the oversize fraction on the screen.

The amount of inorganic filler (C) included in the composition is preferably in a range of 50 to 500 parts by weight, and more preferably 100 to 400 parts by weight, per 100 parts by weight of the epoxy resin (A) and the curing agent (B) combined. A composition with less than 50 parts by weight of the filler may have too large an expansion coefficient and induce cracks in a thermal cycling test. A composition with more than 500 parts by weight of the filler may have an increased viscosity, which may bring about a decline in thin-film penetration.

In the liquid epoxy resin composition of the invention, (D) an organic solvent having a boiling point of 130 to 250° C. is used, especially for the purposes of improving operation efficiency and lowering viscosity. The boiling point of the organic solvent is preferably in the range of 140 to 230° C., more preferably 150 to 230° C. An organic solvent having a boiling point of lower than 130° C. will volatilize off during dispensing or cure, causing formation of voids. An organic solvent having a boiling point of higher than 250° C. will not volatilize off to the last during cure, which can cause a lowering of strength or adhesion.

Examples of the organic solvent include 2-ethoxyethanol, 1,2-propanediol, 1,2-ethanediol, diethylene glycol, xylene, cyclohexanone, cyclohexanol, formamide, acetamide, and diethylene glycol monoethyl ether acetate.

The preferred organic solvents are ester organic solvents. Solvents other than the ester organic solvents are less desirable. For example, alcoholic solvents or organic solvents having hydroxyl groups can markedly exacerbate the storage stability of the composition because hydroxyl groups readily react with amines. For this reason and for safety, ester organic solvents having the general formula (2) are preferred.

R⁴COO—[R⁵—O]ₙ—R⁶ (2)

Herein R⁴ and R⁶ each are a monovalent hydrocarbon group having 1 to 6 carbon atoms, R⁵ is an alkylene group having 1 to 6 carbon atoms, and n is an integer of 0 to 3.

Examples of the monovalent C₁-C₆ hydrocarbon groups represented by R⁴ and R⁶ are as exemplified above for R¹ to R³. Examples of the C₁-C₆ alkylene group represented by R⁵ include ethylene, propylene, methylethylene, butylene, pentene and hexene.

Examples of the ester organic solvents having formula (2) include 2-ethoxyethyl acetate, 2-butoxyethyl acetate, diethylene glycol monoethyl ether acetate, diethylene glycol monobutyl ether acetate, diethylene glycol ethyl ether acetate, and diethylene glycol butyl ether acetate.

The organic solvent (D) is used in an amount of 0.5 to 10 parts by weight, preferably 1 to 10 parts by weight per 100 parts by weight of the epoxy resin (A) and the curing agent (B) combined. Less than 0.5 pbw of the solvent is insufficient for the viscosity-lowering effect whereas more than 10 pbw of the solvent results in a reduced crosslinking density, failing to provide a sufficient strength.

In the liquid epoxy resin composition of the invention, silicone rubbers, silicone oils, liquid polybutadiene rubbers, and thermoplastic resins such as methyl methacrylate-butadiene-styrene copolymers may be included for the stress reduction purpose. The preferred stress reducing agent is a silicone-modified resin in the form of a copolymer which is obtained from an alkenyl group-containing epoxy resin or alkenyl group-containing phenolic resin and an organopolysiloxane of the average compositional formula (3) containing per molecule 20 to 400 silicon atoms and 1 to 5 hydrogen atoms each directly attached to a silicon atom (i.e., SiH groups), by effecting addition of SiH groups to alkenyl groups.

HₐR⁷_{b}Sio_{(4-a-b)/2} (3)

Herein R⁷ is a substituted or unsubstituted monovalent hydrocarbon group, “a” is a number of 0.01 to 0.1, “b” is a number of 1.8 to 2.2, and the sum of a+b is from 1.81 to 2.3.

The substituted or unsubstituted monovalent hydrocarbon group represented by R⁷ preferably has 1 to 10 carbons, and especially 1 to 8 carbons. Illustrative examples include alkyl groups such as methyl, ethyl, propyl, isopropyl, butyl, isobutyl, tert-butyl, hexyl, octyl and decyl; alkenyl groups such as vinyl, allyl, propenyl, butenyl and hexenyl; aryl groups such as phenyl, xylyl and tolyl; aralkyl groups such as benzyl, phenylethyl and phenylpropyl; and halogenated monovalent hydrocarbon groups in which some or all of the hydrogen atoms on the hydrocarbon groups are substituted with halogen atoms (e.g., chlorine, fluorine, bromine), such as fluoromethyl, bromoethyl and trifluoropropyl.

Copolymers having the following structure are preferred.

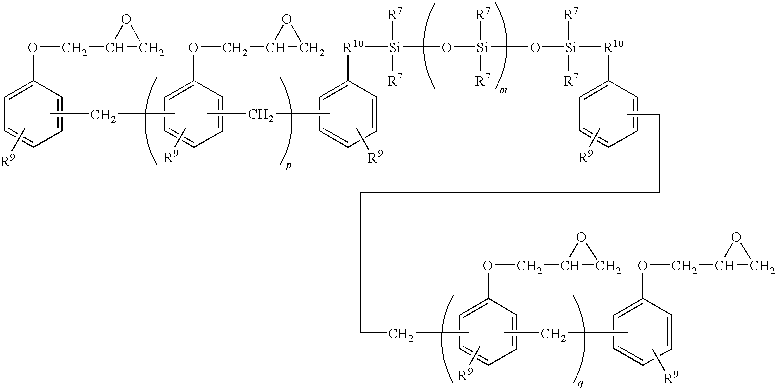

In the above formula, R⁷ is as defined above, R⁹ is a hydrogen atom or a C₁-C₄ alkyl group such as methyl, ethyl, propyl, isopropyl, butyl, isobutyl and tert-butyl, and R¹⁰ is —CH₂CH₂CH₂—, —OCH₂—CH(OH)—CH₂—O—CH₂CH₂CH₂— or —O—CH₂CH₂CH₂—. The letter m is an integer from 4 to 199, and preferably from 19 to 99, p is an integer from 1 to 10, and q is an integer from 1 to 10.

The above-described copolymer is included in the inventive composition such that the amount of diorganopolysiloxane units is 0 to 20 parts by weight, and preferably 2 to 15 parts by weight, per 100 parts by weight of the epoxy resin, whereby stress can be further reduced.

If necessary, the liquid epoxy resin composition may further contain other additives as long as they do not compromise the objects of the invention. Suitable additives include carbon-functional silanes for improving adhesion, pigments (e.g., carbon black), dyes, and antioxidants. It is recommended that the addition of an alkoxy-bearing silane coupling agent as the carbon functional silane adhesion improver is excluded from the present invention although such a coupling agent can be used as the surface treating agent for the filler.

The liquid epoxy resin composition of the invention may be prepared by the simultaneous or discrete agitation, dissolution, mixing and dispersion of a liquid epoxy resin, an aromatic amine curing agent or a melt mixed masterbatch of liquid epoxy resin and aromatic amine curing agent, an inorganic filler, and optionally, an organic solvent and other additives, while carrying out heat treatment if necessary. No particular limitation is imposed on the apparatus used for mixing, agitating, dispersing and otherwise processing the mixture of components. Exemplary apparatus suitable for this purpose include an automated mortar, three-roll mill, ball mill, planetary mixer and bead mill having agitating and heating units incorporated thereto. Use can also be made of suitable combinations of these apparatuses.

For use as a sealant or encapsulant, the liquid epoxy resin composition should desirably have a viscosity of up to 10,000 poises at 25° C., more desirably 10 to 1,000 poises at 25° C.

An ordinary molding method and ordinary molding conditions may be employed when encapsulating semiconductor devices with the inventive composition. It is preferable to carry out an initial hot oven cure at 100 to 120° C. for at least ½ hour, followed by a subsequent hot oven cure at 165° C. for at least 1 hour, especially 1 to 4 hours. A cure time of less than ½ hour during 100 to 120° C. heating may result in void formation after curing. A post-cure time of less than 1 hour during 165° C. heating may yield a cured product having less than sufficient properties.

The semiconductor devices to be encapsulated with the inventive composition are flip chip-type semiconductor devices. Referring to FIG. 1, the flip chip-type semiconductor device includes an organic substrate 1 having an interconnect pattern side on which is mounted a semiconductor chip 3 over a plurality of intervening bumps 2. The gap between the organic substrate 1 and the semiconductor chip 3 (shown in the diagram as gaps between the bumps 2) is filled with an underfill material 4, and the lateral edges of the gap and the periphery of semiconductor chip 3 are sealed with a fillet material 5. The inventive liquid epoxy resin composition is especially suitable in forming the underfill.

When the inventive composition is used as an underfill material, the cured product preferably has a coefficient of thermal expansion of 20 to 40 ppm/° C. below the glass transition temperature (Tg). One effective means of achieving such a coefficient of thermal expansion is by blending 100 to 400 parts by weight of the inorganic filler per 100 parts by weight of the epoxy resin and the curing agent combined.

Sealant used as the fillet material may be a conventional material known to the art. The use as the fillet of a liquid epoxy resin composition of the same type as the present invention is especially preferred. The cured product in this case preferably has a coefficient of thermal expansion of 10 to 20 ppm/° C. below the Tg.

### EXAMPLES

Examples of the invention and comparative examples are given below by way of illustration, and are not intended to limit the invention.

### Examples 1-10 and Comparative Examples 1-2

The components shown in Tables 1 and 2 were mixed to uniformity on a three-roll mill to give twelve resin compositions. These resin compositions were examined by the following tests. The results are also shown in Tables 1 and 2.

[Viscosity]

The viscosity at 25° C. was measured using a BH-type rotary viscometer at a rotational speed of 4 rpm. The viscosity at 25° C. was measured again after holding at 40° C. for 24 hours.

[Penetration Test]

A polyimide-coated silicon chip of 10 mm×10 mm was placed on a FR-4 substrate of 30 mm×30 mm using spacers of approximately 50 μm thick, leaving a gap therebetween. The resin composition was melted on a hot plate at 100° C. and allowed to penetrate into the gap. The time taken until the gap was fully filled with the composition was measured.

[Void Test]

A polyimide-coated silicon chip of 10 mm×10 mm was placed on a FR-4 substrate of 30 mm×30 mm to form a flip chip package having a gap of approximately 50 μm. The composition was introduced into the gap and cured thereat. Using a scanning acoustic microscope C-SAM (SONIX Inc.), the sample was inspected for voiding.

[Glass Transition Temperature (Tg)]

Using a sample of the cured composition measuring 5×5×15 mm, the glass transition temperature was measured with a thermomechanical analyzer at a heating rate of 5° C./min.

[Coefficients of Thermal Expansion (CTE)]

Based on the Tg measurement described above, a coefficient of thermal expansion below Tg (CTE-1) was determined for a temperature range of 50 to 80° C., and a coefficient of thermal expansion above Tg (CTE-2) was determined for a temperature range of 200 to 230° C.

[Bond Strength Test]

On a polyimide-coated silicon chip was rested a frustoconical sample having a top diameter of 2 mm, a bottom diameter of 5 mm and a height of 3 mm. It was cured at 165° C. for 3 hours. At the end of curing, the sample was measured for (initial) shear bond strength. The cured sample was then placed in a pressure cooker test (PCT) environment of 121° C. and 2.1 atm for 336 hours for moisture absorption. At the end of PCT test, shear bond strength was measured again. In each Example, five samples were used, from which an average bond strength value was calculated.

[PCT Peel Test]

A polyimide-coated 10×10 mm silicon chip was stacked on a 30×30 mm FR-4 substrate to form a flip chip package having a gap of approximately 50 μm. An epoxy resin composition was introduced into the gap and cured thereat. The assembly was held at 30° C. and RH 65% for 192 hours and then processed 5 times by IR reflow set at a maximum temperature of 265° C., before the assembly was checked for peeling. The assembly was then placed in a PCT environment of 121° C. and 2.1 atm for 336 hours, after which the assembly was checked for peeling. Peeling was inspected by C-SAM (SONIX Inc.).

[Thermal Shock Test]

A polyimide-coated 10×10 mm silicon chip was stacked on a 30×30 mm FR-4 substrate to form a flip chip package having a gap of approximately 50 μm. An epoxy resin composition was introduced into the gap and cured thereat. The assembly was held at 30° C. and RH 65% for 192 hours and then processed 5 times by IR reflow set at a maximum temperature of 265° C. The assembly was then tested by thermal cycling between −65° C./30 minutes and 150° C./30 minutes. After 250, 500, 750 and 1000 cycles, the assembly was examined for peeling and cracks.

TABLE 1

| Component | Example | | | | | |
|---|---|---|---|---|---|---|
| (pbw) | 1 | 2 | 3 | 4 | 5 | 6 |
| Curing agent A | 26.0 | | | 30.6 | 30.2 | 3.1 |
| Curing agent B | | 29.8 | | | | |
| Curing agent C | | | 22.8 | | | |
| C-300S | | | | | | 36.1 |
| RE303S-L | 37.0 | 35.1 | 38.6 | 34.7 | | 30.4 |
| Epikoat 630H | 37.0 | 35.1 | 38.6 | 34.7 | | 30.4 |
| RE600NM | | | | | 69.8 | |
| (molar ratio of epoxy resin/ | 1.0 | 1.0 | 1.0 | 0.8 | 1.0 | 1.0 |
| curing agent) | | | | | | |
| Spherical silica A | 150 | 150 | 150 | 150 | 150 | 150 |
| KBM403 | 1 | 1 | 1 | 1 | 1 | 1 |
| Copolymer | 4 | 4 | 4 | 4 | 4 | 4 |

Measurement results

| Viscosity (Pa ·s @25° C.) | | 28.8 | 33.5 | 22.8 | 15.8 | 29.2 | 92.2 |
|---|---|---|---|---|---|---|---|
| Viscosity after 40° C./24 hr | | 56.9 | 51.8 | 66.5 | 33.7 | 54.7 | 153 |
| (Pa · s @25° C.) | | | | | | | |
| Penetration time (sec) | | 20 | 25 | 18 | 15 | 25 | 52 |
| Void test | | nil | nil | nil | nil | nil | nil |
| Tg (° C.) | | 138 | 125 | 120 | 130 | 139 | 128 |
| CTE-1 (ppm/° C.) | | 30 | 30 | 29 | 31 | 31 | 32 |
| CTE-2 (ppm/° C.) | | 119 | 118 | 113 | 115 | 115 | 114 |
| PCT peel | After 5 times of IR | no | no | no | no | no | no |
| test | reflow at 265° C. | peeling | peeling | peeling | peeling | peeling | peeling |
| | After PCT 336 hr | no | no | no | no | no | no |
| | | peeling | peeling | peeling | peeling | peeling | peeling |
| Bond | Initial | 196 | 168 | 205 | 194 | 184 | 185 |
| strength | After PCT 336 hr | 126 | 119 | 143 | 157 | 145 | 143 |
| (kgf/cm²) | | | | | | | |
| Failure | 250 cycles | 0 | 0 | 0 | 0 | 0 | 0 |
| (%) | 500 cycles | 0 | 0 | 0 | 0 | 0 | 0 |
| after | 750 cycles | 0 | 0 | 0 | 0 | 0 | 0 |
| thermal | 1000 cycles | 0 | 0 | 0 | 0 | 0 | 0 |
| shock | | | | | | | |
| test | | | | | | | |

TABLE 2

| | | | | | | Comparative | |
|---|---|---|---|---|---|---|---|
| Component | | Example | | | | Example | |
| (pbw) | | 7 | 8 | 9 | 10 | 1 | 2 |
| Curing agent A | | 26.0 | 26.0 | 26.0 | 26.0 | | 0.9 |
| C-300S | | | | | | 40.6 | 29.9 |
| RE303S-L | | 37.0 | 37.0 | 37.0 | 37.0 | 29.7 | 69.2 |
| Epikoat 630H | | 37.0 | 37.0 | 37.0 | 37.0 | 29.7 | |
| (molar ratio of epoxy resin/ | | 1.0 | 1.0 | 1.0 | 1.0 | 1.0 | 1.0 |
| curing agent) | | | | | | | |
| Spherical silica A | | 150 | 250 | | 250 | 150 | 150 |
| Spherical silica B | | | | 250 | | | |
| Solvent A | | 2.5 | 2.5 | 2.5 | | | |
| Solvent B | | | | | 2.5 | | |
| KBM403 | | 1 | 1 | 1 | 1 | 1 | 1 |
| Copolymer | | 4 | 4 | 4 | 4 | 4 | 4 |
| Measurement results | | | | | | | |
| Viscosity (Pa · s @ 25° C.) | | 11.6 | 47.0 | 51.4 | 53.9 | 108 | 95 |
| Viscosity after 40° C./24 hr | | 22.1 | 88.4 | 89.7 | 95.8 | 311 | 301 |
| (Pa · s @ 25° C.) | | | | | | | |
| Penetration time (sec) | | 11 | 58 | 61 | 63 | 180 | 177 |
| Void test | | nil | nil | nil | nil | voids | voids |
| Tg (° C.) | | 94 | 90 | 93 | 125 | 120 | 111 |
| CTE-1 (ppm/° C.) | | 32 | 25 | 25 | 26 | 31 | 30 |
| CTE-2 (ppm/° C.) | | 113 | 92 | 91 | 93 | 120 | 121 |
| PCT peel | After 5 times of IR | no | no | no | no | no | no |
| test | reflow at 265° C. | peeling | peeling | peeling | peeling | peeling | peeling |
| | After PCT 336 hr | no | no | no | no | no | no |
| | | peeling | peeling | peeling | peeling | peeling | peeling |
| Bond | Initial | 175 | 174 | 191 | 169 | 156 | 171 |
| strength | After PCT 336 hr | 124 | 147 | 134 | 127 | 117 | 122 |
| (kgf/cm²) | | | | | | | |
| Failure | 250 cycles | 0 | 0 | 0 | 0 | 0 | 0 |
| (%) | 500 cycles | 0 | 0 | 0 | 0 | 0 | 0 |
| after | 750 cycles | 0 | 0 | 0 | 0 | 0 | 0 |
| thermal | 1000 cycles | 0 | 0 | 0 | 0 | 30 | 0 |
| shock | | | | | | | |
| test | | | | | | | |

Components:
Curing agent A: diethyltoluenediamine (Mw = 178)
Curing agent B: dimethylthiotoluenediamine (Mw = 214.4)
Curing agent C: dimethyltoluenediamine (Mw = 150)
C-300S: tetraethyldiaminophenylmethane, Nippon Kayaku Co., Ltd.
RE303S-L: bisphenol F-type epoxy resin, Nippon Kayaku Co., Ltd.
Epikoat 630H: trifunctional epoxy resin, Japan Epoxy Resin Co., Ltd.

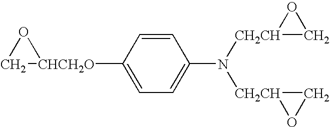

RE600NM: 5-methylresorcinol diglycidyl ether, Nippon Kayaku Co., Ltd.

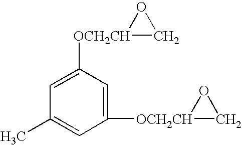

Silica A: spherical silica produced by the sol-gel method and having an average particle size
of 3.2 μm and containing 0.01 wt % of a fraction having a size of 25 μm or greater.
Silica B: spherical silica produced by the sol-gel method and having an average particle size
of 3.6 μm and containing 0.08 wt % of a fraction having a size of 25 μm or greater.

The content of a 25-μm or greater size fraction was measured by the sieve analysis method below.

Sieve Analysis

Silica and deionized water were mixed in a weight ratio of 1:9. The mixture was subjected to ultrasonic treatment for fully disintegrating agglomerates and sieved through a screen having an opening of 25 μm. The oversize fraction on the screen was weighed. Analysis was made five times. An average of five measurements is reported in % by weight.
Solvent A: 2-butoxyethyl acetate, b.p. 192° C.
Solvent B: PGMEA, b.p. 146° C.
KBM403: silane coupling agent, γ-glycidoxypropyltrimethoxy-silane, Shin-Etsu Chemical Co., Ltd.
Copolymer: the addition reaction product of

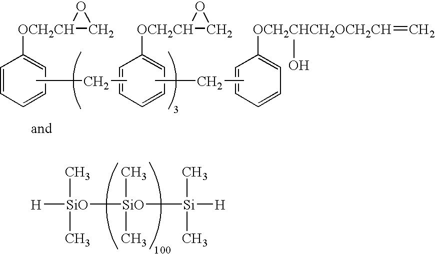

It has been demonstrated that the liquid epoxy resin composition of the invention has a low viscosity to ensure ease of working, cures into a cured product which has improved adhesion to the surface of silicon chips and especially to photosensitive polyimide resins and nitride films, and offers an encapsulated semiconductor device that does not suffer a failure even when the temperature of reflow after moisture absorption elevates from the conventional temperature of nearly 240° C. to 260-270° C., does not deteriorate under hot humid conditions as encountered in PCT (120° C./2.1 atm), and does not undergo peeling or cracking over several hundred cycles of thermal cycling between −65° C. and 150° C. The composition is thus best suited as an encapsulant for flip chip semiconductor devices.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. A liquid epoxy resin composition comprising:
(A) a liquid epoxy resin containing three or less epoxy functional groups in a molecule, being liquid at normal temperature, and comprising an epoxy resin of the following structural formula (5): 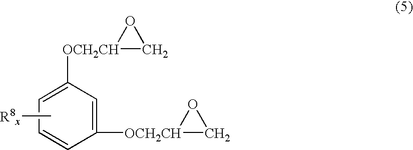
wherein R⁸ is a monovalent hydrocarbon group having 1 to 20 carbon atoms, and the subscript x is an integer of 1 to 4;
(B) an aromatic amine curing agent comprising at least 5% by weight of an aromatic amine compound having the following general formula (1): 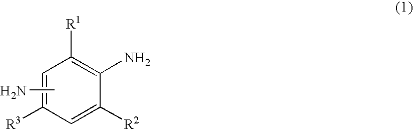
wherein each of R¹ to R³ is independently a monovalent hydrocarbon group having 1 to 6 carbon atoms, CH₃S— or C₂H₅S—, and
wherein the liquid epoxy resin (A) and the aromatic amine curing agent (B) are present in a molar ratio (A)/(B) of from 0.7/1 to 1.2/1; and
(C) an inorganic filler having an average particle size of 0.1 to 5 μm in an amount of 50 to 500 parts by weight per 100 parts by weight of the epoxy resin (A) and the curing agent (B) combined.

2. The composition of claim 1, wherein the inorganic filler (C) has an average particle size of 0.1 to 5 μm and contains not more than 0.1% by weight of a fraction having a particle size of at least one-half of a gap size in a flip chip type semiconductor device.

3. The composition of claim 1, wherein the liquid epoxy resin (A) comprises at least 25% by weight of the epoxy resin of the structural formula (5), based on the entire amount of epoxy resins.

4. The composition of claim 1, wherein R⁸ is a monovalent hydrocarbon group having 1 to 3 carbon atoms.

5. The composition of claim 1, wherein the epoxy resin of structural formula (5) is 5-methylresorcinol diglycidyl ether.

6. The composition of claim 1, further comprising a silicone-modified epoxy resin in the form of a copolymer which is obtained from an alkenyl group-containing epoxy resin or phenolic resin and an organopolysiloxane having the average compositional formula (3):
HₐR⁷_{b}SiO_{(4-a-b)/2} (3)
wherein R⁷ is a substituted or unsubstituted monovalent hydrocarbon group, “a” is a number of 0.01 to 0.1, “b” is a number of 1.8 to 2.2, and 1.81≦a+b≦2.3, said organopolysiloxane containing per molecule 20 to 400 silicon atoms and 1 to 5 hydrogen atoms each directly attached to a silicon atom (i.e., SiH groups), by effecting addition of SiH groups to alkenyl groups.

7. The composition of claim 6, wherein the copolymer has the following structure: 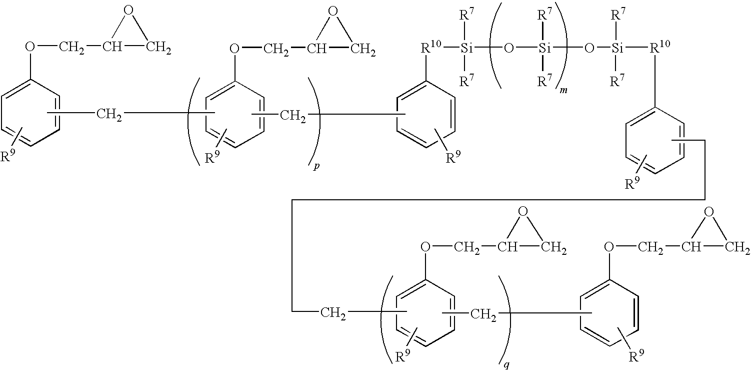
wherein R⁷ is a substituted or unsubstituted monovalent hydrocarbon group, R⁹ is a hydrogen atom or a C₁-C₄ alkyl group, R¹⁰ is
—CH₂CH₂CH₂—, —OCH₂CH(OH)—CH₂—O—CH₂CH₂CH₂— or —O—CH₂CH₂CH₂—, the letter m is an integer from 4 to 199, p is an integer from 1 to 10, and q is an integer from 1 to 10.

8. A flip chip semiconductor device which is encapsulated with the liquid epoxy resin composition of claim 1 in the cured state as an underfill.

9. A flip chip semiconductor device which is encapsulated with the liquid epoxy resin composition of claim 6 in the cured state as an underfill.

10. A flip chip semiconductor device which is encapsulated with the liquid epoxy resin composition of claim 7 in the cured state as an underfill.
